(19) United States
(12) Patent Application Publication
(10) Pub. No.: US 2007/0023846 A1
(43) Pub. Date: Feb. 1, 2007

(54) Transistor

(76) Inventor: Isaiah Watas Cox, Baltimore, MD (US)

Correspondence Address: Borealis Technical Limited, 23545 NW Skyline Blvd, North Plains, OR, 97133-9204, US

(21) Appl. No.: 11/495,804

(22) Filed: Jul. 28, 2006

(30) Foreign Application Priority Data
Jul. 29, 2005 (GB) GB0515635.1

(51) Int. Cl. H01L 29/76

(52) U.S. Cl. 257/401; 257/E29.028; 257/E29.135

(57) ABSTRACT

In a first aspect, there is provided a field effect transistor comprising a gate having a modified shape having sharply defined geometric patterns or indents of a dimension that creates de Broglie wave interference. According to a second aspect of the present invention, there is provided a spin transistor comprising a first region defining an emitter, a second region defining a semiconductor base, and a third region defining a collector, wherein: the emitter includes a spin polarizer for spin-polarizing charge carriers to be injected from the emitter to the base; and the collector includes a spin filter for spin-filtering charge carriers received at the collector from the base; characterized in that the emitter further includes a tunneling barrier arranged to tunnel inject the spin-polarized charge carriers into the semiconductor base having a modified shape comprising sharply defined geometric patterns or indents of a dimension that creates de Broglie wave interference. According to a third aspect, there is provided a field effect transistor comprising a gate dielectric having a modified shape having sharply defined geometric patterns or indents of a dimension that creates de Broglie wave interference.

### CROSS-REFERENCE TO RELATED APPLICATIONS

This application claims the benefit of U.K. Provisional Patent App. No. GB0515635.1, filed Jul. 29, 2005.

### BACKGROUND OF THE INVENTION

Increased packing density of transistors for highly miniaturized LSIs produced in the 30-nanometer and below technology has been improved by simultaneously decreasing the dimensions of both the height and the width of each part of the transistor, such as thickness of insulating layers, gate length, etc. However this is not without deleterious effects.

A typical metal-oxide-semiconductor (MOS) transistor 9 according to the prior art is shown in FIG. 1. Dielectric layer 20 is formed on a semiconductor 10 and a transistor gate structure 30 is formed on the dielectric layer 20. In a self-aligned dopant implantation process, the drain and source extension regions 40 are formed following the formation of the gate structure 30. These drain and source extension regions 40 can be n-type or p-type for NMOS or PMOS transistors respectively. Typically the drain and source extension regions 40 are more lightly doped than the source and drain regions 60 and are referred to as lightly doped drain (LDD) or moderately doped drain (MDD) extension regions depending on the relative doping concentration of the extension regions 40 with respect to the source and drain regions 60. Following the formation of the LDD or MDD regions 40, sidewall structures 50 are formed adjacent to the gate structure 30. The source and drain regions 60 are the formed by implanting dopant species into the semiconductor 10. The implanted dopant species used to form the source and drain regions 60 are self-aligned to the sidewall structures 50. Metal silicide 70 is then formed on both the source and drain 60 and on the gate structure 30 to reduce the resistance associated with these regions.

However, The LDD or MDD regions 40 are relatively lightly doped and therefore contribute parasitic resistance to the MOS transistor. Parasitic resistance reduces the performance of the MOs transistor by reducing the voltage that appears across the channel region. As the gate length of the MOS transistor is reduced the parasitic resistances associated with the LDD and MDD regions will become a large limitation in improving the performance of the transistor.

In U.S. Pat. No. 6,919,605, a MOS transistor with reduced parasitic resistances is disclosed, which comprises a semiconductor layer formed adjacent to the sidewall structures and the source and drain regions, and source and drain extension regions are formed in the semiconductor layer and the semiconductor. Metal silicide layers are formed on the semiconductor layer over the source and drain regions and source and drain extension regions. This is illustrated in FIG. 2, which shows a gate structure 30 formed on a semiconductor 10. Source and drain extension regions 130 are formed in the semiconductor 10 adjacent to the gate structure 30. Metal silicide layers 140 are formed on the extension regions 130 and sidewall structures 155, 165, and 175 are formed over the metal silicide layers 140. Source and drain regions 120 are formed in the semiconductor 10, and metal silicide layers 180 are formed on the source and drain regions 120.

Another shortcoming is that the shorter channel between source and drain means that it becomes harder for the gate to control the flow of current between them. Doping the channel overcomes this shortcoming to some extent, as does using a substrate formed of, for example, strained silicon.

Moreover, the thickness of gate dielectric is required to be sufficiently thin, so that the equivalent SiO2 thickness [also referred to as “EOT (Equivalent Oxide Thickness)”] for the gate dielectric is sufficiently less than 1 nm. However, as the thickness of a conventional gate SiO₂ dielectric becomes less than about 2 nm, gate leakage current increases due to direct carrier tunneling, thereby causing problems, such as increase of power consumption, etc. In order to overcome these problems, high-k gate dielectric materials, which have a dielectric constant higher than that of SiO₂, are employed. High-k gate dielectric materials can suppress gate leakage current with a low EOT being kept, since its physical thickness (actual thickness) is much thicker than that of SiO₂. The need to maintain strong coupling between the gate and the channel means that highly-doped polysilicon gates are used which are almost as conductive as metal.

In U.S. Pat. No. 6,914,312 a Metal-Insulator-Semiconductor (MIS) type field effect transistor is disclosed which has a rare-earth metal oxynitride layer with a high dielectric constant, which can maintain good interface characteristics. The field effect transistor includes a gate dielectric having a substantially crystalline rare-earth metal oxynitride layer containing one or more metals selected from rare-earth metals, oxygen, and nitrogen. The rare-earth metal oxynitride layer contacts a predetermined region of a Si semiconductor substrate, and the nitrogen exists at the interface between the rare-earth metal oxynitride layer and the Si semiconductor substrate, and in the bulk of the rare-earth metal oxynitride. The transistor further includes a gate electrode formed on the gate dielectric and source and drain regions, one being formed at one side of the gate electrode and the other being formed at the other side of the gate electrode in the Si semiconductor substrate. This approach provides a MIS-type field effect transistor having a high-k gate dielectric with good interfacial properties. FIG. 3 is a cross-sectional view of the basic structure of an n-channel MISFET formed on a device formation region of a p-type Si substrate 1 isolated by device isolation regions 2. The MISFET includes gate dielectric 3 formed on the device formation region, a gate electrode 4 of polycrystalline silicon formed on the gate dielectric 3, a diffusion layer (source/drain regions) 5 formed at both sides of the gate electrode 4 in the device formation region, to which an n-type impurity is implanted, a dielectric 6 of, e.g., a CVD silicon nitride layer, formed at both sides of the gate electrode 4, and Al wirings 8 connected to the gate electrode 4 and the source/drain regions 5 via contact holes formed in an interlayer dielectric 7 formed of, e.g., a CVD silicon oxide layer.

In U.S. Pat. No. 6,919,608 a spin transistor is provided comprising a first region defining an emitter, a second region defining a semiconductor base, and a third region defining a collector. The emitter includes a spin polarizer for spin-polarizing charge carriers to be injected from the emitter to the base; and the collector includes a spin filter for spin-filtering charge carriers received at the collector from the base. The emitter further includes a tunneling barrier arranged to tunnel inject the spin-polarized charge carriers into the semiconductor base. The use of a tunneling barrier reduces the formation of suicides and other contaminants, since a silicon/insulator interface is formed, rather than a silicon/metal interface. Thus, there is a significant reduction in spin depolarization relative to the prior art. Moreover, the tunneling barrier height and width may be readily varied, and this in turn allows the point of injection into the band-structure of the silicon base to be varied over a wide range whilst maintaining constant injection current density. The spin injection energy may then be selected so as to maximize the spin sensitivity of the spin transistor. The collector may further include a second tunneling barrier, Schottky barrier, Ohmic barrier or p-n semiconductor junction for removal of the spin-polarized carriers from the semiconductor base. Referring to FIG. 4, spin transistor 210 comprises a spin injector 250 formed of a ferromagnetic material and constituting the emitter 220 of a three-terminal device, a spin filter 270 also formed of a ferromagnetic material and constituting a collector 240, and a semiconductor base 230 region. A tunneling barrier 260 is formed of an insulating metal oxide such as aluminum oxide between the emitter 220 and the base 230. The tunneling barrier 260 reduces the degree of spin depolarization as carriers are injected into the base 230, and permits selection of spin injection energy. In preferred embodiments, a second tunneling barrier 280 may be formed between the base 230 and the collector 240.

The behavior of semiconductor devices depends chiefly on the physics of band alignment and the existence of interface states. The ability to tune the barrier height/band-offset in semiconductor devices is thus is strongly desirable. For example, the contact resistance to a semiconductor can be dramatically improved with a reduction in its Schottky barrier height. The ohmic contact issue is particularly relevant for wide band gap semiconductors with doping difficulties, such as the p-type GaN. Another interface where the ability to tune the Schottky barrier height is beneficial is between high permittivity (high-K) gate dielectrics and metal gates, which is an important element of next-generation ULSI devices. In addition, metal gates help to keep the crucial effective oxide thickness (EOT) small by avoiding reaction with the high-k dielectric and thereby obviating the need for a (lower-k) buffer layer. One philosophy for metal gate is to choose a metal with a work function that matches roughly the mid-gap point of the semiconductor. However, to be able to maintain the threshold gate voltage for the field effect transistor at a convenient voltage, especially at scaled-back power supply voltages, it is desirable to have separate Fermi level positions for the gates on n-type and p-type channels. For this purpose, one needs to control the Schottky barrier height (SBH) between the metal gate and the high-K dielectric. The most successful approaches to modify the SBH has been to insert a very thin layer of material between the metal and the semiconductor. For example, layers of insulators, semiconductors, molecular dipoles, and chemical passivation, formed on the semiconductor surface, have been shown to modify the barrier height of Schottky contact. The manner by which the SBH is affected by the interlayer is rather unpredictable and system-specific.

In U.S. Pat. No. 7,074,498, the use of electrodes having a modified shape and a method of etching a patterned indent onto the surface of a modified electrode, which increases the Fermi energy level inside the modified electrode, leading to a decrease in electron work function is disclosed. FIG. 5 shows the shape and dimensions of a modified electrode 66 having a thin metal film 68 on a substrate 62. Indent 64 has a width b and a depth Lx relative to the height of metal film 60. Film 68 comprises a metal whose surface should be as planar as possible as surface roughness leads to the scattering of de Broglie waves. Metal film 68 is given sharply defined geometric patterns or indent 64 of a dimension that creates a De Broglie wave interference pattern that leads to a decrease in the electron work function, thus facilitating the emissions of electrons from the surface and promoting the transfer of elementary particles across a potential barrier. The surface configuration of modified electrode 66 may resemble a corrugated pattern of squared-off, “u”-shaped ridges and/or valleys. Alternatively, the pattern may be a regular pattern of rectangular “plateaus” or “holes,” where the pattern resembles a checkerboard. The walls of indent 64 should be substantially perpendicular to one another, and its edges should be substantially sharp. The surface configuration comprises a a substantially planar slab of a material having on one surface one or more indents of a depth approximately 5 to 20 times a roughness of said surface and a width approximately 5 to 15 times said depth. The walls of the indents are substantially perpendicular to one another, and the edges of the indents are substantially sharp. Typically the depth of the indents is ≧λ/2, wherein λ is the de Broglie wavelength, and the depth is greater than the surface roughness of the metal surface. Typically the width of the indents is >>λ, wherein λ is the de Broglie wavelength. Typically the thickness of the film is a multiple of the depth, preferably between 5 and 15 times said depth, and preferably in the range 15 to 75 nm.

### BRIEF SUMMARY OF THE INVENTION

From the foregoing, it may be appreciated that a need has arisen for improved materials for use in transistors, such as improved gate materials for use in FET transistors, and improved tunneling barriers for use in spin transistors.

In order to achieve the above-described object, a field effect transistor according to a first aspect of the present invention includes: a gate having a modified shape comprising sharply defined geometric patterns or indents of a dimension that creates de Broglie wave interference; and source and drain regions, one being formed at one side of the gate electrode and the other being formed at the other side of the gate electrode in the semiconductor substrate.

According to a second aspect of the present invention, there is provided a spin transistor comprising a first region defining an emitter, a second region defining a semiconductor base, and a third region defining a collector, wherein: the emitter includes a spin polarizer for spin-polarizing charge carriers to be injected from the emitter to the base; and the collector includes a spin filter for spin-filtering charge carriers received at the collector from the base; characterized in that the emitter further includes a tunneling barrier arranged to tunnel inject the spin-polarized charge carriers into the semiconductor base having a modified shape comprising sharply defined geometric patterns or indents of a dimension that creates de Broglie wave interference. The collector may further include a second tunneling barrier, Schottky barrier, Ohmic barrier or p-n semiconductor junction for removal of the spin-polarized carriers from the semiconductor base.

According to a third aspect of the present invention, a field effect transistor according to a first aspect of the present invention includes: a gate dielectric having a modified shape comprising sharply defined geometric patterns or indents of a dimension that creates de Broglie wave interference; a gate electrode formed on the gate dielectric; and source and drain regions, one being formed at one side of the gate electrode and the other being formed at the other side of the gate electrode in the semiconductor substrate.

### BRIEF DESCRIPTION OF THE SEVERAL VIEWS OF THE DRAWING

For a more complete explanation of the present invention and the technical advantages thereof, reference is now made to the following description and the accompanying drawing in which:

FIGS. 1-3 are schematics of field effect transistors;

FIG. 4 is a schematic of a spin transistor; and

FIGS. 5-6 are schematics of modified materials useful as gate or tunneling barrier components.

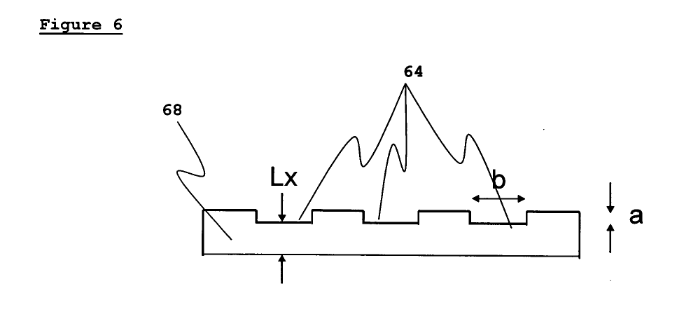

### DETAILED DESCRIPTION OF THE INVENTION

Referring now to FIG. 6, which shows a modified gate structure 68 of the present invention, having indents 64 along one side of said gate structure. Preferably said one or more indents have a depth approximately 5 to 20 times a roughness of the surface into which they indent, and a width approximately 5 to 15 times the depth. Preferably the walls of the indents are substantially perpendicular to one another, and the edges of the indents are substantially sharp. Typically the depth of the indents a is ≧λ/2, wherein λ is the de Broglie wavelength, and the depth is greater than the surface roughness of the metal surface. Typically the width b of the indents is >>λ, wherein 80 is the de Broglie wavelength. Typically the thickness of the slab Lx is a multiple of the depth, preferably between 5 and 15 times said depth, and preferably in the range 15 to 75 nm.

The indented gate may resemble a corrugated pattern of squared-off, “u”-shaped ridges and/or valleys. Alternatively, the pattern may be a regular pattern of rectangular “plateaus” or “holes,” where the pattern resembles a checkerboard.

Typically, gate material 68 is a metal. Choice of the gate material 68, and of the depth a of the indents, permits control of the Schottky barrier height (SBH) between the gate and the high-K dielectric.

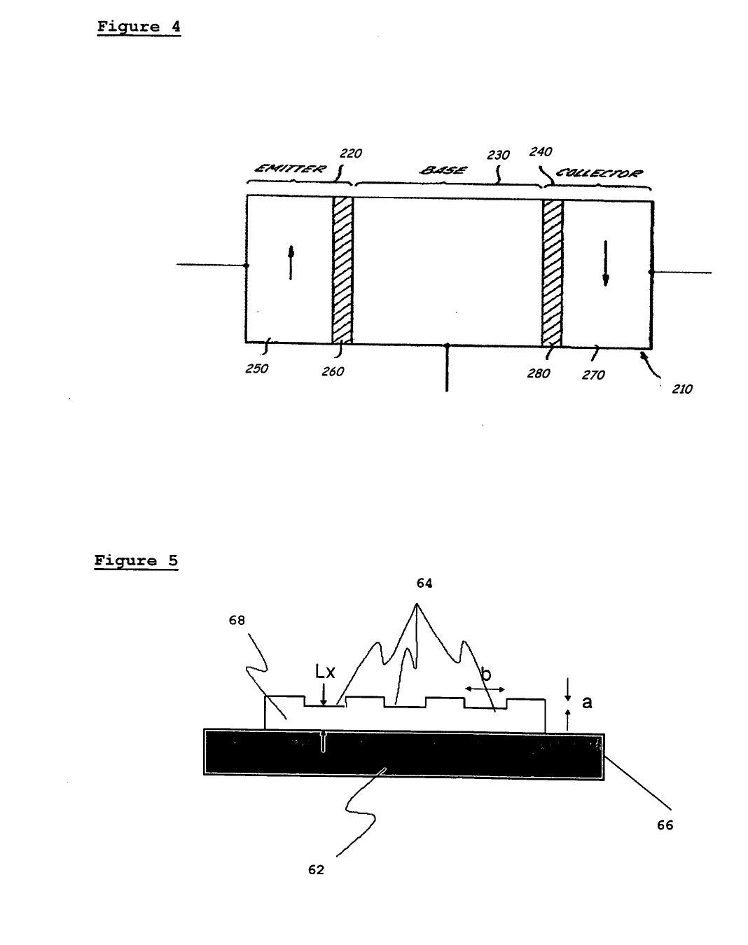

In a second aspect of the present invention, the gate structure described above may also be applied to the tunneling barriers of a spin transistor, which is comprised of a base, a collector having a spin filter, and an emitter having a spin polarizer and a tunneling barrier. Referring now to FIG. 4, a spin transistor 210 comprises a spin injector 250 formed of a ferromagnetic material and constituting the emitter 220 of a three-terminal device, a spin filter 270 also formed of a ferromagnetic material and constituting a collector 240, and a semiconductor base 230 region. A tunneling barrier 260 is formed of an insulating metal oxide such as aluminum oxide between the emitter 220 and the base 230. The tunneling barrier 260 reduces the degree of spin depolarization as carriers are injected into the base 230, and permits selection of spin injection energy. In preferred embodiments, a second tunneling barrier 280 may be formed between the base 30 and the collector 240. The tunnel barrier has the structure shown in FIG. 6. The collector may further include a second tunneling barrier, Schottky barrier, Ohmic barrier or p-n semiconductor junction for removal of the spin-polarized carriers from the semiconductor base.

The gate structure may be applied to a wide range of devices, and Table 1 provides an exemplary list.

TABLE 1
Devices to which the modified gate structure
of the present invention may be applied

| Device | Type | Example |
|---|---|---|
| I. Field Effect Transistors | JFET | MESFET |
| | IGFET/MOSFET | MISFET |
| | | HFET |
| | | CMOS |
| II. Other Gated Transistors | SET | |
| | quantum transistors | |
| | spin transistors | |
| | (tunnel barrier) | |
| III. Combinations of I and II | spinFET | |
| | quantum well FET | |
| | resonant gate FET | |

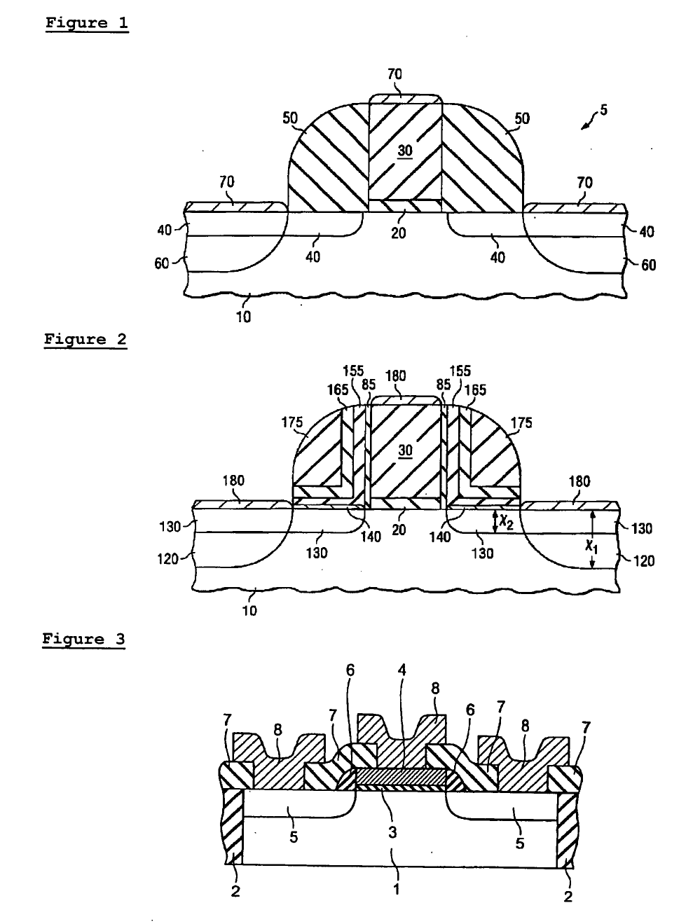

In particular the gate structure of the present invention may replace gate 30 in the MOSFET of FIGS. 1 and 2 and gate 4 in the MISFET of FIG. 3. The inclusion of the embodiments detailed in FIGS. 1 to 3 is meant by way of example only rather than to limit the scope of the invention.

In a third aspect of the present invention, and referring to FIG. 1, the modified surface features are applied to the dielectric material 20. According to this aspect, dielectric layer 20 is formed on a semiconductor 10 and a transistor gate structure 30 is formed on the dielectric layer 20. Dielectric layer 20 has the geometric structure shown in FIG. 6.

1. A transistor, comprising: a source region; a drain regions; and a gate structure; characterized in that the gate structure comprises a substantially planar slab of a material having on one surface one or more indents of a depth approximately 5 to 20 times a roughness of said surface and a width approximately 5 to 15 times said depth.

2. The transistor of claim 1 in which walls of said indents are substantially perpendicular to one another.

3. The transistor of claim 1 in which edges of said indents are substantially sharp.

4. The transistor of claim 1 in which said gate comprises a metal.

5. The transistor of claim 1 wherein said depth≧λ/2, wherein λ is the de Broglie wavelength.

6. The transistor of claim 1 wherein said width>>λ, wherein x is the de Broglie wavelength.

7. The transistor of claim 1 wherein a thickness of said slab is in the range 15 to 75 nm.

8. A transistor comprising a first region defining an emitter, a second region defining a semiconductor base, and a third region defining a collector, wherein:
the emitter includes a spin polarizer for spin-polarizing charge carriers to be injected from the emitter to the base; and
the collector includes a spin filter for spin-filtering charge carriers received at the collector from the base;
the emitter further includes a tunnelling barrier arranged to tunnel inject the spin-polarized charge carriers into the semiconductor base;
characterized in that the tunnelling barrier comprises a substantially planar slab of a material having on one surface one or more indents of a depth approximately 5 to 20 times a roughness of said surface and a width approximately 5 to 15 times said depth.

9. The transistor of claim 8 in which walls of said indents are substantially perpendicular to one another.

10. The transistor of claim 8 in which edges of said indents are substantially sharp.

11. The transistor of claim 8 wherein said depth≧λ/2, wherein λ is the de Broglie wavelength.

12. The transistor of claim 8 wherein said width>>λ, wherein λ is the de Broglie wavelength.

13. The transistor of claim 8 wherein a thickness of said slab is in the range 15 to 75 nm.

14. A transistor, comprising: a source region; a drain regions; a gate structure; and an insulator region; characterized in that the insulator comprises a substantially planar slab of a material having on one surface one or more indents of a depth approximately 5 to 20 times a roughness of said surface and a width approximately 5 to 15 times said depth.

15. The transistor of claim 14 in which walls of said indents are substantially perpendicular to one another.

16. The transistor of claim 14 in which edges of said indents are substantially sharp.

17. The transistor of claim 14 wherein said depth≧λ/2, wherein λ is the de Broglie wavelength.

18. The transistor of claim 14 wherein said width>>λ, wherein λ is the de Broglie wavelength.

19. The transistor of claim 14 wherein a thickness of said slab is in the range 15 to 75 nm.
